(19) United States
(12) Patent Application Publication
(10) Pub. No.: US 2026/0337764 A1
(43) Pub. Date: Oct. 29, 2026

(54) METHOD FOR FORMING RUTHENIUM OXIDE FILM AND METHOD FOR MANUFACTURING SEMICONDUCTOR DEVICE COMPRISING SAME

(71) Applicant: JUSUNG ENGINEERING CO., LTD., Gwangju-si, Gyeonggi-do (KR)

(72) Inventors: Young Woon KIM, Gwangju-Si, Gyeonggi-do (KR); Chul Joo HWANG, Gwangju-Si, Gyeonggi-do (KR)

(21) Appl. No.: 19/471,729

(22) PCT Filed: Apr. 8, 2024
(86) PCT No.: PCT/KR2024/004628

§ 371 Date: Oct. 2, 2025

(30) Foreign Application Priority Data
Apr. 13, 2023 (KR) 10-2023-0048847
Apr. 4, 2024 (KR) 10-2024-0045966

(51) Int. Cl. C23C 16/40; C23C 16/455; C23C 16/46; C23C 16/56; H10P 14/43; H10W 20/00

(52) U.S. Cl. CPC C23C 16/405; C23C 16/45527; C23C 16/46; C23C 16/56; H10P 14/43; H10W 20/032

(57) ABSTRACT

A method for forming a ruthenium oxide film according to an embodiment of the present invention may comprise the steps of: forming a ruthenium film by spraying a precursor containing ruthenium (Ru) toward a substrate; forming a ruthenium oxide film by spraying an oxygen-containing gas onto the ruthenium film; and forming plasma to expose the ruthenium oxide film to the plasma. According to embodiments of the present invention, a ruthenium oxide film with a high oxygen content can be formed. Thus, the quality of the ruthenium oxide film can be improved, leading to an enhancement in performance of the ruthenium oxide film included in a semiconductor device.

### TECHNICAL FIELD

The present disclosure relates to a method for forming a ruthenium oxide film and a method for manufacturing a semiconductor device including the same, and more particularly, to a method for forming a ruthenium oxide film, the method capable of increasing the content of oxygen, and a method for manufacturing a semiconductor device including the ruthenium oxide film.

### BACKGROUND ART

A capacitor includes a substrate, a diffusion barrier film formed on the substrate, a lower electrode formed on the diffusion barrier film, a dielectric film formed on the lower electrode, and an upper electrode formed on the dielectric film. The lower electrode may be formed of a ruthenium metal film, and the diffusion barrier film may be formed of a ruthenium oxide film. Here, the diffusion barrier film is a film formed to suppress or prevent ruthenium (Ru) contained in the lower electrode from moving to or diffusing into the substrate.

In forming the ruthenium oxide film, a precursor containing ruthenium (Ru) is sprayed to form a ruthenium metal film on the substrate, and then an oxygen gas is sprayed toward the ruthenium metal film. However, ruthenium (Ru) is a precious metal material which is not easily oxidized. Accordingly, there is a problem in that the oxygen content of the ruthenium oxide film is low, resulting in degrading the performance of the ruthenium oxide film. That is, there is a problem in that the ruthenium oxide film cannot suppress or prevent ruthenium (Ru) of the lower electrode from moving to the substrate.

In order to solve the problem of a low content of oxygen contained in the ruthenium oxide film, the substrate is heated to a high temperature of approximately 800 °C or higher. However, since the ruthenium metal film is formed at a temperature of 500 °C or lower, the ruthenium oxide film and the ruthenium metal film cannot be formed in situ. That is, the ruthenium metal film should be formed by forming the ruthenium oxide film in one deposition device, and then moving a substrate on which the ruthenium oxide film is formed to another deposition device. Therefore, there is a problem in that the process becomes complicated.

### Prior Art Document

(Patent Document 1) Korean Patent Registration No. KR 0434489

### DISCLOSURE OF THE INVENTION

### Technical Problem

The present disclosure provides a method for forming a ruthenium oxide film, the method capable of increasing the content of oxygen, and a method for manufacturing a semiconductor device including the ruthenium oxide film.

The present disclosure also provides a method for forming a ruthenium oxide film, the method capable of forming a ruthenium oxide film by effectively increasing the content of oxygen, and a method for manufacturing a semiconductor device including the ruthenium oxide film.

### Technical Solution

In accordance with an exemplary embodiment, a method for forming a ruthenium oxide film includes spraying a precursor containing ruthenium (Ru) toward a substrate to form a ruthenium film, spraying an oxygen-containing gas onto the ruthenium film to form a ruthenium oxide film, and forming plasma to expose the ruthenium oxide film to the plasma.

In the forming of the plasma, an oxygen-containing gas may be used to form the plasma.

The oxygen-containing gas may include one or a combination of two or more of oxygen (O₂), ozone (O₃), and nitrous oxide (N₂O).

The forming of the plasma may include additionally using an inert gas in addition to the oxygen-containing gas to form the plasma, wherein the inert gas may include one or a combination of two or more of argon (Ar) and helium (He).

The oxygen content of the ruthenium oxide film exposed to the plasma may be higher than the oxygen content of the ruthenium oxide film before the exposure to the plasma.

A film forming cycle (CY_{f}) including the forming of the ruthenium film and the forming of the ruthenium oxide film may be performed a plurality of times, and the plurality of times of the film forming cycle (CYf) may be continuously performed.

The exposing of the ruthenium oxide film to the plasma may be performed after continuously performing the film forming cycle (CY_{f}) a plurality of times.

In the forming of the plasma, the forming of the plasma by additionally using the inert gas in addition to the oxygen-containing gas may include spraying the oxygen-containing gas and the inert gas toward the ruthenium oxide film, and generating the plasma using the sprayed oxygen-containing gas and the inert gas, wherein in the spraying of the oxygen-containing gas and the inert gas, the spraying may be performed such that the flow rate of the oxygen-containing gas is greater than that of the inert gas.

In the spraying of the oxygen-containing gas in the film forming cycle (CY_{f}), the inert gas may be sprayed there together, wherein the inert gas may include one or a combination of two or more of argon (Ar) and helium (He).

In the spraying of the oxygen-containing gas and the inert gas in the film forming cycle (CY_{f}), the spraying may be performed such that the flow rate of the oxygen-containing gas is greater than that of the inert gas.

In the forming of the ruthenium film, the forming of the ruthenium oxide film, and the exposing to the plasma, the temperature of the substrate may be controlled to approximately 250 °C to approximately 450 °C.

In accordance with another exemplary embodiment, a method for manufacturing a semiconductor device includes forming a ruthenium metal film on a substrate inside a chamber, and before or after the forming of the ruthenium metal film, forming a ruthenium oxide film in situ inside the chamber in which the ruthenium metal film is formed, wherein the forming of the ruthenium oxide film may include the above-described method for forming a ruthenium oxide film.

In the forming of the ruthenium metal film and the forming of the ruthenium oxide film, the temperature of the substrate may be controlled to approximately 250 °C to approximately 450 °C.

### Advantageous Effects

According to exemplary embodiments, it is possible to form a ruthenium oxide film having a high oxygen content. Therefore, it is possible to improve the quality of the ruthenium oxide film, and accordingly, it is possible to improve the performance of the ruthenium oxide film included in a semiconductor device.

### BRIEF DESCRIPTION OF THE DRAWINGS

FIG. 1 is a conceptual diagram showing a semiconductor device including a ruthenium oxide (RuO₂) film formed by a method in accordance with exemplary embodiments;

FIG. 2 is a conceptual diagram for describing a method for forming a ruthenium oxide film by a method in accordance with an exemplary embodiment;

(a) to (c) of FIG. 3 are process diagrams for describing a deposition step P_{f} in accordance with an exemplary embodiment;

FIG. 4 is a process diagram for describing a plasma exposure step Pₚ in accordance with an exemplary embodiment;

FIG. 5 is a conceptual diagram for describing a method for forming a ruthenium oxide film in accordance with another exemplary embodiment;

FIG. 6 is a diagram showing a case in which the ruthenium oxide (RuO₂) film formed in accordance with the exemplary embodiments is formed in an upper portion of a ruthenium metal film; and

FIG. 7 is a diagram showing a case in which the ruthenium oxide (RuO₂) film formed in accordance with the exemplary embodiments is formed between a substrate and a ruthenium metal film, and in an upper portion of the ruthenium metal film.

### MODE FOR CARRYING OUT THE INVENTION

Hereinafter, embodiments of the present disclosure will be described in more detail with reference to the accompanying drawings. However, the present disclosure is not limited to the embodiments disclosed below, but will be implemented in various forms different from each other, and the embodiments are merely to complete the present disclosure, and are provided to fully convey the scope of the present disclosure to those skilled in the art. The drawings may be exaggerated to describe the embodiments of the present disclosure, and like reference numerals in the drawings refer to like elements.

The present disclosure relates to a method for forming a ruthenium oxide film, the method capable of improving the quality of a ruthenium oxide film. More specifically, the present disclosure relates to a method for forming a ruthenium oxide film, the method capable of forming a ruthenium oxide film having an improved oxygen content.

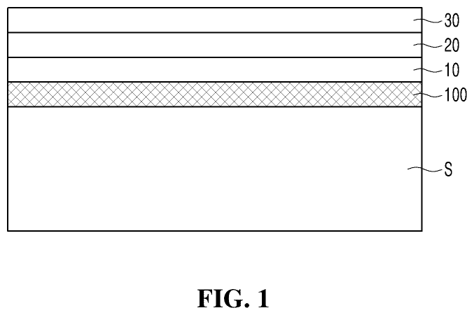

FIG. 1 is a conceptual diagram showing a semiconductor device including a ruthenium oxide (RuO₂) film formed by a method in accordance with exemplary embodiments.

The semiconductor device including the ruthenium oxide (RuO₂) film may be, for example, a capacitor. Referring to FIG. 1, the capacitor may include a substrate S, a lower conductive film 10 formed on the substrate S, a dielectric film 20 formed on the lower conductive film 10, and an upper conductive film 30 formed on the dielectric film 20.

The substrate S may be a semiconductor substrate. As a more specific example, the substrate S may be a wafer, or may be any one of a Si wafer, a GaAs wafer, and a SiGe wafer. Also, the substrate S may be made of any one of glass, a metal, plastic, a polymer film, and a dielectric material.

The dielectric film 20 may be formed of a dielectric material including a metal oxide. As a more specific example, the dielectric film 20 may be formed of any one of ZrO₂, Al₂O₃, TiO₂, TaO₂, and HfO_{2.}

The lower conductive film 10 and the upper conductive film 30 are formed of a conductive material. At this time, the lower conductive film 10 may be formed of a ruthenium (Ru) metal film, and the upper conductive film 30 may be formed of a conductive material other than ruthenium (Ru). Also, the upper conductive film 30 may be formed of a ruthenium (Ru) metal film, and the lower conductive film 10 may be formed of a conductive material other than ruthenium (Ru). In addition, the lower conductive film 10 and the upper conductive film 30 may be formed of a ruthenium metal film.

Hereinafter, it is described that the lower conductive film 10 is formed of a ruthenium metal film. Accordingly, for convenience of description, the lower conductive film and the ruthenium metal film will be referred to as the same reference numeral ‘10.’ and described.

Meanwhile, if the lower conductive film 10 made of a ruthenium metal film is formed directly on one surface of the substrate S, e.g., a Si wafer, the ruthenium (Ru) contained in the lower conductive film 10 may move to or diffuse into the substrate S. This becomes a factor which degrades the performance of the semiconductor device. Accordingly, as shown in FIG. 1, a ruthenium oxide film 100 is formed between the substrate S and the lower conductive film 10. At this time, the ruthenium oxide film 100 serves to suppress or preventing the ruthenium (Ru) contained in the lower conductive film 10 from moving to the substrate S. That is, the ruthenium oxide film 100 formed between the substrate S and the lower conductive film 10 is a diffusion barrier film which suppresses and prevents the movement of the ruthenium (Ru).

The ruthenium oxide film 100 formed by the method in accordance with exemplary embodiments may be, as shown in FIG. 1, a diffusion barrier film formed between the substrate S and the lower conductive film 10.

Here, the ruthenium oxide film 100 and the lower conductive film 10 stacked on the substrate S may be components of a lower electrode. That is, the lower electrode may include the ruthenium oxide film 100 formed on the substrate S, and the lower conductive film 10 formed on the ruthenium oxide film 100. In addition, the upper conductive film 30 may be an upper electrode.

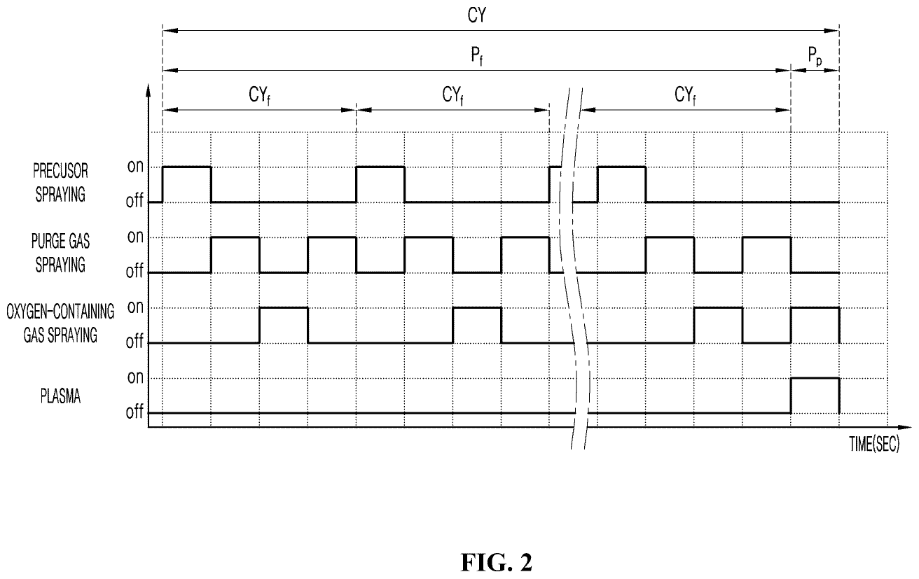

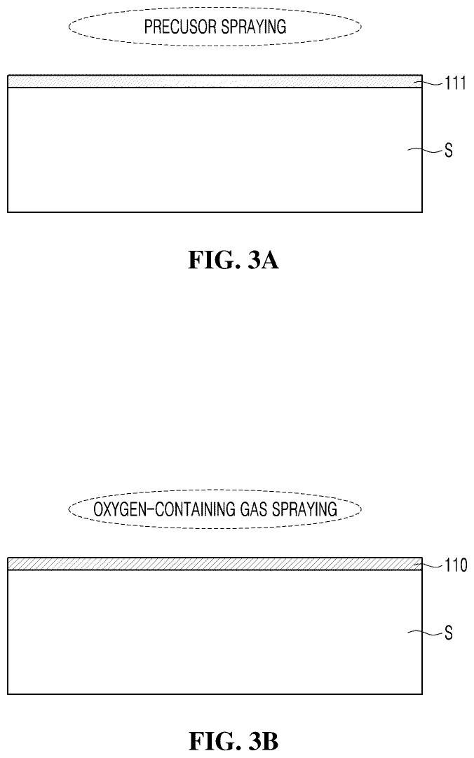

Hereinafter, with reference to FIG. 2 to FIG. 4, a method for forming a ruthenium oxide film in accordance with an exemplary embodiment will be described. At this time, the formation of a ruthenium oxide film on one surface of the substrate S will be described as an example.

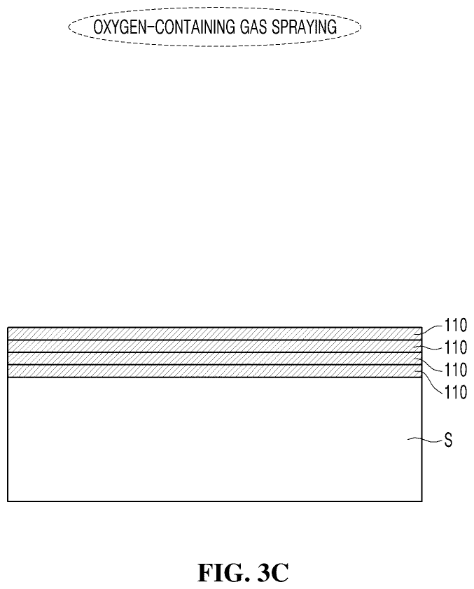

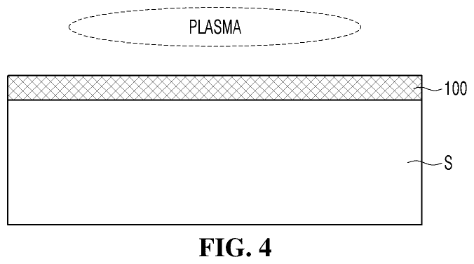

FIG. 2 is a conceptual diagram for describing a method for forming a ruthenium oxide film by the method in accordance with an exemplary embodiment. (a) to (c) of FIG. 3 are process diagrams for describing a film formation step P_{f} in accordance with an exemplary embodiment. FIG. 4 is a process diagram for describing a plasma exposure step Pₚ in accordance with an exemplary embodiment.

In FIG. 2, ‘ON’ indicates that a raw material or gas for forming a film is sprayed, or plasma is generated, and ‘OFF’ indicates that the spraying of the raw material or gas is stopped or completed, or plasma is not generated.

Referring to FIG. 2, the method for forming a ruthenium oxide film may include the film formation step P_{f} of forming a ruthenium oxide (RuO₂) film, and the plasma exposure step Pₚ of exposing the ruthenium oxide (RuO₂) film formed in the film formation step P_{f} to plasma to increase the oxygen content of the ruthenium oxide (RuO₂) film.

Hereinafter, for convenience of description, a ruthenium oxide (RuO₂) film formed in the film formation step P_{f} is referred to as a ‘primary ruthenium oxide film 110,’ and a film formed by exposing the primary ruthenium oxide film 110 formed in the film formation step P_{f} to plasma is referred to as a ‘secondary ruthenium oxide film 100.

The method for forming the ruthenium oxide film 100 by reflecting the above is described as follows. The method for forming the ruthenium oxide film 100 may include the film formation step P_{f} of forming the primary ruthenium oxide film 110, and the plasma exposure step Pₚ of forming the secondary ruthenium oxide film 100, which is a ruthenium oxide film obtained by exposing the primary ruthenium oxide film 110 to plasma, thereby having an increased oxygen content compared to the primary ruthenium oxide film 110.

A process including the film formation step P_{f} and the plasma exposure step Pₚ may be defined as one process cycle CY. In other words, a process in which the film formation step P_{f}—the plasma exposure step Pₚ are performed in the order may be defined as one process cycle CY. In addition, the process cycle CY may be performed a plurality of times.

Here, the primary ruthenium oxide film 110 is a ruthenium oxide film formed by oxidizing ruthenium, and the secondary ruthenium oxide film 100 is a ruthenium oxide film formed after exposing the primary ruthenium oxide film 110 to plasma. Accordingly, both the primary ruthenium oxide film 110 and the secondary ruthenium oxide film 100 may be referred to as a ruthenium oxide (RuO₂) film. However, the primary ruthenium oxide film 110 and the secondary ruthenium oxide film 100 formed by the method in accordance with an exemplary embodiment are different in the content of oxygen. That is, the content of oxygen of the secondary ruthenium oxide film 100 is higher than that of the primary ruthenium oxide film 110.

In addition, the secondary ruthenium oxide film 100 is a ruthenium oxide film which is a final product to be formed by the method in accordance with an exemplary embodiment. Accordingly, the ruthenium oxide film which is the final product to be formed by the method in accordance with an exemplary embodiment and the secondary ruthenium oxide film may be described using the same reference numeral. That is, the reference numeral ‘100’ to be described below may indicate both the secondary ruthenium oxide film and the ruthenium oxide film which is the final product.

Hereinafter, the film formation step P_{f} will be described with reference to FIG. 2 and FIG. 3.

Referring to FIG. 2, and (a) to (c) of FIG. 3, the film formation step P_{f} includes spraying a precursor (precursor spraying step) containing ruthenium (Ru) toward the substrate S to form a ruthenium film 111 and spraying an oxygen-containing gas toward the ruthenium film 111 to form the primary ruthenium oxide film 110.

In addition, the film formation step P_{f} may further include at least one of spraying a purge gas (first purge step) between the precursor spraying step and the oxygen-containing gas spraying step, and spraying a purge gas (second purge step) after the oxygen-containing gas spraying step is completed. Here, an argon (Ar) gas may be used as the purge gas.

In addition, ‘the precursor spraying step—the primary purge step—the oxygen-containing gas spraying step—the secondary purge step’ may be set to one cycle (hereinafter, referred to as a film formation cycle CY_{f}). That is, the film formation step P_{f} may include the film formation cycle CY_{f}, and the film formation cycle CY_{f} may include ‘the precursor spraying step—the primary purge step—the oxygen-containing gas spraying step—the secondary purge step.’ In addition, the film formation step P_{f} may include a plurality of the film formation cycles CY_{f}, and at this time, the plurality of the film formation cycles CY_{f} may be continuously performed. In addition, in the film formation cycle CY_{f}, at least one of the first purge step and the second purge step may be omitted.

Hereinafter, each step of the film formation cycle CY_{f} will be described in more detail.

In the spraying of a precursor, a precursor containing or including ruthenium (Ru) is sprayed toward the substrate S. That is, a precursor containing ruthenium (Ru) is sprayed into a chamber in which the substrate S is loaded. Here, a raw material of the precursor containing ruthenium (Ru) may be, for example, bis(ethylcyclopentadienyl)ruthenium ((EtCp)₂Ru). If the precursor containing ruthenium (Ru) is sprayed as described above, the precursor is deposited or adsorbed onto one surface of the substrate S to form a film containing ruthenium (Ru), that is, the ruthenium film 111, as shown in (a) of FIG. 3.

When the step of spraying the precursor is completed, a purge gas is sprayed into the chamber in which the substrate S is charged, thereby performing primary purge. At this time, for example, an argon (Ar) gas may be used as the purge gas.

When the primary purge is completed, an oxygen-containing gas is sprayed into the chamber in which the substrate S is charged, as shown in (b) of FIG. 3. Here, the oxygen-containing gas may include, for example, one or a combination of two or more of oxygen (O₂), ozone (O₃), and nitrous oxide (N₂O). When the oxygen-containing gas is sprayed, oxygen (O) penetrates into the ruthenium film 111, and as a result, the ruthenium film 111 and the oxygen (O) react with each other. That is, the ruthenium film 111 may be oxidized by reacting with oxygen contained in the oxygen-containing gas. Accordingly, the primary ruthenium oxide film 110, which is a ruthenium oxide (RuO₂) film containing ruthenium (Ru) and oxygen, is formed.

The oxygen-containing gas sprayed in the film formation step P_{f} is a gas sprayed to be reacted with the ruthenium film 111, and thus, may be referred to as a ‘reactant gas.’ Accordingly, the reactant gas may be described as an oxygen-containing gas.

When the step of spraying the oxygen-containing gas is completed, a purge gas is sprayed into the chamber in which the substrate S is charged, thereby performing secondary purge. At this time, the purge gas may be the same gas as that in the primary purge step, and for example, an argon (Ar) gas may be used.

In performing the precursor spraying step, the first purge step, the oxygen-containing gas spraying step, and the second purge step as described above, the temperature of the substrate may be controlled to approximately 250 °C to approximately 450 °C. That is, the film formation cycle CY_{f} is performed in a state in which the temperature of the substrate S is controlled to approximately 250 °C to approximately 450 °C. More specifically, the temperature of a susceptor installed in a chamber of a deposition device is controlled to control the temperature of the substrate S supported on the susceptor to approximately 250 °C to approximately 450 °C. Thereafter, the film formation cycle CY_{f} of spraying a precursor, a purge gas, and an oxygen-containing gas into the chamber is performed. Accordingly, the primary ruthenium oxide film 110, which is a ruthenium oxide film, is formed on the substrate S.

Thereafter, the film formation cycle CY_{f} including the precursor spraying step, the first purge step, the oxygen-containing gas spraying step, and the second purge step as described above is repeated a plurality of times and performed. Accordingly, as shown in (c) of FIG. 3, a plurality of the primary ruthenium oxide films 110 are stacked on the substrate S.

In (c) of FIG. 3, the plurality of the primary ruthenium oxide films 110 are separately shown in order to distinguish the primary ruthenium oxide film 110 formed by each of the plurality of the film formation cycles CY_{f}, but the stacked plurality of the primary ruthenium oxide films 110 may be integrated.

As described above, when the oxygen-containing gas is sprayed toward the ruthenium film 111, ruthenium (Ru) contained in the ruthenium film 111 reacts with oxygen, so that the primary ruthenium oxide film 110, which is a ruthenium oxide film, is formed. However, the primary ruthenium oxide film 110 thus formed has a low content of oxygen (O). More specifically, the primary ruthenium oxide film 110 may have the content of oxygen (O) which is lower than the content ruthenium (Ru), or may have the content of oxidation (O) which is the same as the content of ruthenium (Ru). In other words, the ratio of the content of ruthenium (Ru) to the content of oxygen (O) contained in the primary ruthenium oxide film 110 may be 1:1 or less (content of ruthenium: content of oxygen=1:1 or less). Here, if the ratio of the content of ruthenium (Ru) to the content of oxygen (O) is 1:1, it may indicate that the content of ruthenium (Ru) and the content of oxygen (O) are the same, and if the ratio of the content of ruthenium (Ru) to the content of oxygen (O) is less than 1:1, it may indicate that the content of oxygen is less than the content of ruthenium (Ru).

If the content of oxygen contained in a ruthenium oxide film is low, the function of the ruthenium oxide film may be degraded. In order to describe the above more specifically, the case in which the ruthenium oxide film 100 is formed between the lower conductive film 10 and the substrate S as described with reference to FIG. 1 will be described. Here, the ruthenium oxide film 100 is a diffusion barrier film.

If the content of oxygen contained in the ruthenium oxide film 100 is low, the ruthenium oxide film 100 may not suppress or prevent ruthenium (Ru) contained in the lower conductive film 10 from moving to the substrate S. That is, the ruthenium oxide film 100 has a low content of oxygen (O) contained therein, and thus, has degraded quality as the diffusion barrier film.

Therefore, in an embodiment, the primary ruthenium oxide film 110 formed in the film formation step P_{f} is exposed to plasma to increase the content of oxygen (O) contained in the primary ruthenium oxide film 110. In other words, the primary ruthenium oxide film 110 is exposed to plasma to form the secondary ruthenium oxide film 100 having an increased oxygen content compared to that of the primary ruthenium oxide film 110. At this time, plasma (oxygen plasma) containing oxygen is formed, and primary ruthenium oxide film 110 is exposed to the oxygen plasma to form the secondary ruthenium oxide film 100 having an increased oxygen content.

Hereinafter, referring to FIG. 2 and FIG. 4, the plasma exposure step Pₚ for forming the secondary ruthenium oxide film 100 will be described.

Referring to FIG. 2, the plasma exposure step Pₚ includes spraying an oxygen-containing gas to generate plasma containing oxygen. That is, the plasma exposure step Pₚ includes spraying an oxygen-containing gas into a chamber in which the substrate S is charged or toward the substrate S, and generating oxygen plasma by using the sprayed oxygen-containing gas. In addition, the generating of the oxygen plasma may include applying power for the plasma generation. At this time, for example, radio frequency (RF) power may be applied to at least one among the chamber, a susceptor on which the substrate S is seated inside the chamber, and a spray part for spraying the oxygen-containing gas into the chamber. In addition, the oxygen-containing gas may include, for example, one or a combination of two or more of oxygen (O₂), ozone (O₃), and nitrous oxide (N₂O). As such, if the RF power is applied and the oxygen-containing gas is sprayed, plasma containing oxygen, that is, oxygen plasma, may be generated inside the chamber. Accordingly, as shown in FIG. 4, the primary ruthenium oxide film 110 formed on the substrate S is exposed to the plasma.

When the primary ruthenium oxide film 110 is exposed to the oxygen plasma, oxygen (O) contained in the oxygen plasma penetrates into the primary ruthenium oxide film 110. That is, oxygen ions generated during the formation of the oxygen plasma penetrate into the primary ruthenium oxide film 110. At this time, compared to a case in which an oxygen-containing gas is sprayed without forming oxygen plasma, if oxygen plasma is formed, it is possible to increase the amount of oxygen penetrating into the primary ruthenium oxide film 110. A detailed description thereof is as follows. Oxygen contained in an oxygen-containing gas is unionized oxygen. However, when the oxygen-containing gas is sprayed to generate plasma, oxygen ions are generated. In addition, the rate at which ionized oxygen (oxygen ions) moves toward the primary ruthenium oxide film 110 is higher than the rate at which unionized oxygen moves toward the primary ruthenium oxide film 110. Accordingly, by forming oxygen plasma after forming the primary ruthenium oxide film 110, it is possible to increase the content of oxygen contained in the primary ruthenium oxide film 110. In addition, compared to a case in which the primary ruthenium oxide film 110 is formed, and then only an oxygen-containing gas is sprayed onto the primary ruthenium oxide film 110 (no generation of oxygen plasma), if oxygen plasma is formed, it is possible to effectively increase the amount of oxygen penetrating into the primary ruthenium oxide film 110.

Therefore, the secondary ruthenium oxide film 100, which is a ruthenium oxide film having an increased oxygen content compared to the primary ruthenium oxide film 110, may be formed. At this time, the secondary ruthenium oxide film 100 may have the content of oxygen, which is higher than the content of ruthenium (Ru). In other words, the ratio of the content of ruthenium (Ru) to the content of oxygen (O) may be greater than 1:1 (content of ruthenium: content of oxygen=greater than 1:1). More specifically, the ratio of the content of ruthenium (Ru) to the content of oxygen (O) may be 1:2 or greater (content of ruthenium: content of oxygen=1:2 or greater).

As such, if the content of oxygen contained in the secondary ruthenium oxide film 100 is high, the function of the secondary ruthenium oxide film 100 may be improved. In order to describe the above more specifically, the case in which a ruthenium oxide film is formed between the lower conductive film 10 and the substrate S as described with reference to FIG. 1 will be described. Here, the ruthenium oxide film 100 is a diffusion barrier film, and is a secondary ruthenium oxide film formed through the steps of (a) and (b) of FIG. 3 and FIG. 4. Accordingly, the reference numeral ‘100’ illustrated in FIG. 1 will be referred to as a ‘ruthenium oxide film’ and described.

If the oxygen content of the ruthenium oxide film 100 formed between the lower conductive film 10 and the substrate S increases, the ruthenium oxide film 100 may effectively suppress or prevent ruthenium (Ru) contained in the lower conductive film 10 from moving to the substrate S. That is, as the content of oxygen (O) contained in the ruthenium oxide film 100 increases, the function of the ruthenium oxide film 100 as a diffusion barrier film is improved.

In addition, in performing the plasma exposure step Pₚ, the temperature of the substrate S may be the same as the temperature in the above-described film formation step P_{f}. In addition, in performing the plasma exposure step Pₚ, the temperature of the substrate S may be controlled to be different from the temperature in the film formation step P_{f} by approximately ±30 °C. As a more specific example, in performing the plasma exposure step Pₚ, the temperature of the substrate S may be controlled to approximately 250 °C to approximately 450 °C. At this time, a method for controlling the temperature of the substrate S is the same as described above in the film formation step P_{f}, and thus, a description thereof will be omitted.

As such, even if the temperature of the substrate S is controlled to a low temperature of approximately 250 °C to approximately 450 °C, it is possible to form a ruthenium oxide film having an improved oxygen content. That is, typically, in order to increase the oxygen content of a ruthenium oxide film, the temperature of a substrate is controlled to a high temperature of approximately 800 °C. On the other hand, in an embodiment, even if the substrate S is heated to a low temperature of approximately 250 °C to approximately 450 °C, it is possible to form the ruthenium oxide film 100 having an improved oxygen content. This is because the primary ruthenium oxide film 110 is formed, and then the primary ruthenium oxide film 110 is exposed to oxygen plasma. That is, by exposing the primary ruthenium oxide film 110 to oxygen plasma, it is possible to allow oxygen to be sufficiently penetrated into the primary ruthenium oxide film 110 even if the substrate S is not heated to a high temperature of approximately 800 °C. Therefore, the ruthenium oxide film 100 containing sufficient oxygen may be formed at a low temperature of approximately 250 °C to approximately 450 °C.

In addition, the ruthenium metal film 10 formed in a lower portion or upper portion of the ruthenium oxide film 100 is formed at approximately 250 °C to approximately 450 °C. Accordingly, the ruthenium oxide film 100 and the ruthenium metal film 10 may be formed in situ. That is, the ruthenium oxide film 100 is formed inside a chamber of one deposition device, and then the ruthenium metal film 10 may be formed inside the chamber in which the ruthenium oxide film 100 is formed. Therefore, in stacking the ruthenium oxide film 100 and the ruthenium metal film 10, there is an effect of simplifying the process and saving time.

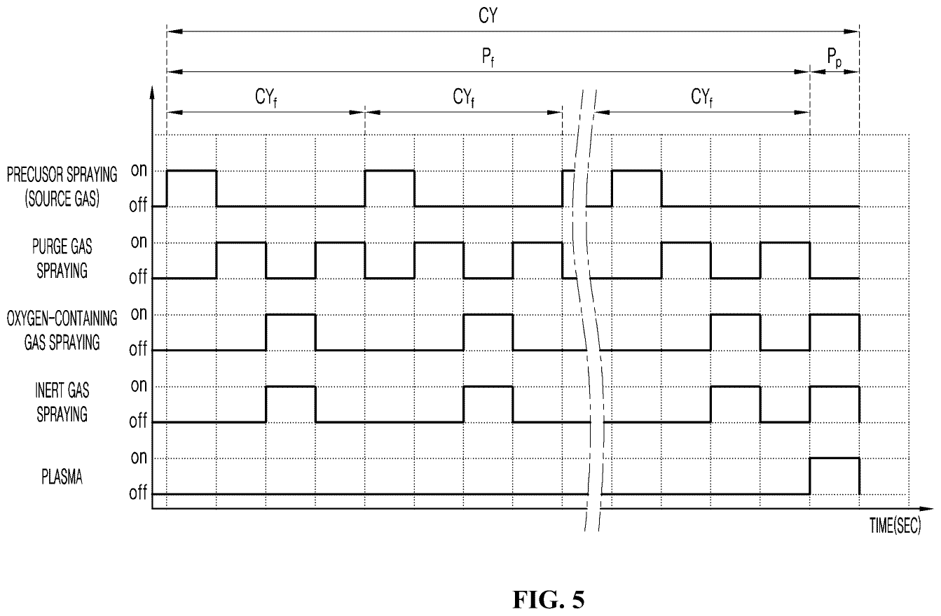

FIG. 5 is a conceptual diagram for describing a method for forming a ruthenium oxide film in accordance with another exemplary embodiment.

In FIG. 5, ‘ON’ indicates that a raw material or gas for forming a film is sprayed, or plasma is generated, and ‘OFF’ indicates that the spraying of the raw material or gas is stopped or completed, or plasma is not generated.

In the exemplary embodiment described with reference to FIG. 2 and FIG. 3, it has been described that an oxygen-containing gas is sprayed in the film formation step P_{f} and the plasma exposure step Pₚ. However, the embodiment is not limited thereto, and an inert gas may be sprayed together when the oxygen-containing gas is sprayed in the film formation step P_{f} and the plasma exposure step Pₚ.

Hereinafter, with reference to FIG. 5, a method for forming a ruthenium oxide film in accordance with another exemplary embodiment will be described. At this time, descriptions which are the same as those described in the exemplary embodiment will be omitted or briefly described.

Referring to FIG. 5, the method for forming a ruthenium oxide film in accordance with the another exemplary embodiment may include a film formation step P_{f} of forming a primary ruthenium oxide film 110, and a plasma exposure step Pₚ of forming a secondary ruthenium oxide film 100 obtained by exposing the primary ruthenium oxide film 110 to plasma containing oxygen, thereby having an increased oxygen content.

In addition, the film formation step P_{f} includes spraying a precursor containing ruthenium (Ru) toward a substrate S to form a ruthenium film 111 and spraying an oxygen-containing gas toward the ruthenium film 111 to form the primary ruthenium oxide film 110, which is a ruthenium oxide film.

In addition, the film formation step P_{f} may further include at least one of spraying a purge gas (first purge step) between the precursor spraying step and the oxygen-containing gas spraying step, and spraying a purge gas (second purge step) after the oxygen-containing gas spraying step is completed. Here, an argon (Ar) gas may be used as the purge gas.

In summary, the film formation step P_{f} in accordance with the another exemplary embodiment may include the precursor spraying step, the primary purge step, the oxygen-containing gas spraying step, and the secondary purge step. In addition, ‘the precursor spraying step—the primary purge step—the oxygen-containing gas spraying step—the secondary purge step’ may be set to one film formation cycle CY_{f}.

In the method in accordance with the another exemplary embodiment, the precursor spraying step, the primary purge step, and the secondary purge step are performed in the same manner as in the method described in the exemplary embodiment. Therefore, descriptions of the above steps will be omitted.

In the oxygen-containing gas spraying step of the film formation step P_{f} in accordance with the another exemplary embodiment, an inert gas is sprayed together. That is, when the oxygen-containing gas is sprayed onto the ruthenium film 111, the inert gas is sprayed together. At this time, the inert gas may include one or a combination of two or more of argon (Ar) and helium (He). The reason why the oxygen-containing gas and the inert gas are sprayed together is that plasma is formed by using the oxygen-containing gas and the inert gas in the subsequent plasma exposure step Pₚ.

A specific reason for spraying the oxygen-containing gas and the inert gas together in the film formation step P_{f} will be described gain after describing the plasma exposure step Pₚ first.

Referring to FIG. 5, the plasma exposure step Pₚ includes spraying an oxygen-containing gas and an inert gas, and generating plasma by using the sprayed oxygen-containing gas and the inert gas. At this time, the inert gas may include one or a combination of two or more of argon (Ar) and helium (He). As such, in the another exemplary embodiment, plasma is generated by spraying an oxygen-containing gas and an inert gas, so that the plasma generated at this time is plasma containing oxygen and an inert element (one or a combination of two or more of Ar and He). Accordingly, the plasma containing the oxygen and the inert element may be referred to as a mixed plasma.

The generating of the mixed plasma by using the oxygen-containing gas and the inert gas may be the same as described in the exemplary embodiment, except that an inert gas is additionally supplied. That is, the generating of the mixed plasma includes spraying an oxygen-containing gas and an inert gas into a chamber in which the substrate S is charged or toward the substrate S, and generating plasma by using the sprayed oxygen-containing gas and the inert gas. In addition, the generating of the plasma may include applying power for the plasma generation. At this time, for example, radio frequency (RF) power may be applied to at least one among the chamber, a susceptor on which the substrate S is seated inside the chamber, and a spray part for spraying the oxygen-containing gas into the chamber. The oxygen-containing gas may include, for example, one or a combination of two or more of oxygen (O₂), ozone (O₃), and nitrous oxide (N₂O). The spray part may mix and then spray the oxygen-containing gas and the inert gas. In addition, a spray part for spraying an oxygen-containing gas and a spray part for spraying an inert gas may be separately provided, so that the oxygen-containing gas and the inert gas may be sprayed through separate spray parts, respectively. If the oxygen-containing gas and the inert gas are sprayed and the RF power is applied, plasma containing oxygen and an inert element, that is, a mixed plasma, is generated in the chamber. Accordingly, the primary ruthenium oxide film 110 formed on the substrate S is exposed to the mixed plasma.

When the primary ruthenium oxide film 110 is exposed to the mixed plasma, oxygen (O) penetrates into the primary ruthenium oxide film 110. That is, oxygen ions generated during the generation of the mixed plasma move to and penetrate into the primary ruthenium oxide film 110. At this time, since the plasma is generated by spraying the inert gas together in addition to the oxygen-containing gas, oxygen may be further effectively penetrated into the primary ruthenium oxide film 110. That is, the secondary ruthenium oxide film 100 may be formed by further effectively increasing the oxygen content.

This is because the density of the mixed plasma formed by spraying the oxygen-containing gas and the inert gas together is higher than that of plasma formed by spraying only an oxygen-containing gas. A detailed description thereof is that an inert element such as argon (Ar) and helium (He) may be discharged at a lower energy than oxygen. Therefore, compared to plasma formed by spraying only an oxygen-containing gas, mixed plasma formed by spraying an oxygen-containing gas and an inert gas (one or a combination of two or more of argon (Ar) and helium (He)) together has a higher density. That is, it is possible to form high-density plasma by spraying and discharging an oxygen-containing gas and an inert gas. In addition, if the density of the plasma increases, the rate at which oxygen ions move to the primary ruthenium oxide film 100 may increase, and accordingly, the amount of oxygen ions penetrating into the primary ruthenium oxide film 100 for the same duration of time may increase.

Therefore, by exposing the primary ruthenium oxide film to the mixed plasma generated by spraying the oxygen-containing gas and the inert gas, it is possible to further effectively increase the content of oxygen contained in the primary ruthenium oxide film 110. That is, compared to a case in which oxygen plasma is formed by spraying only an oxygen-containing gas (exemplary embodiment), the case in which mixed plasma is formed by spraying an oxygen-containing gas and an inert gas (another exemplary embodiment) may effectively increase the amount of oxygen penetrating into the primary ruthenium oxide film 100. Accordingly, compared to the exemplary embodiment, the another exemplary embodiment may form the secondary ruthenium oxide film 100 by further effectively increasing the content of oxygen. In other words, the oxygen content of the ruthenium oxide film 100 may be further effectively increased in the case of the another exemplary embodiment, compared to the exemplary embodiment.

As such, plasma is formed by additionally spraying an inert gas in addition to the oxygen-containing gas in the plasma exposure step Pₚ. Accordingly, in the another exemplary embodiment, an inert gas is sprayed together when the oxygen-containing gas is sprayed in the film formation step P_{f}, which is performed before the plasma exposure step Pₚ. That is, the oxygen-containing gas and the inert gas are sprayed together in the oxygen-containing gas spraying step of the film formation step P_{f}. In addition, it is preferable that the same type of inert gas is used as the inert gas sprayed in the film formation step P_{f} and the plasma exposure step Pₚ. This is to stably form plasma, when the plasma is formed by spraying the oxygen-containing gas and the inert gas in the plasma exposure step Pₚ. For example, in the oxygen-containing gas spraying step of the film formation step P_{f}, only an oxygen-containing gas is sprayed without spraying an inert gas. Then, in the subsequent plasma exposure step Pₚ, an oxygen-containing gas and an inert gas are sprayed together to form plasma. In this case, there is a problem in that plasma energy is rapidly increased by the inert gas. That is, if a state in which there is no inert gas present inside a chamber is maintained in the film formation step P_{f}, and then plasma is generated by supplying an inert gas into the chamber in the plasma exposure step Pₚ, unstable plasma may be generated due to a rapidly increased plasma energy caused by the inert gas. This is because argon (Ar) and helium (He) are easily discharged at a lower energy than oxygen.

Therefore, in the film formation step P_{f} in accordance with the another exemplary embodiment, in the oxygen-containing gas spraying step, the oxygen-containing gas and the inert gas are sprayed together. Accordingly, plasma may be stably formed in the plasma exposure step Pₚ.

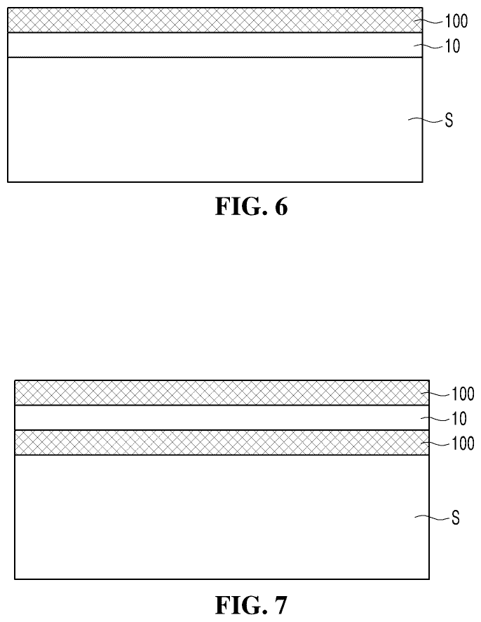

FIG. 6 is a diagram showing a case in which the ruthenium oxide (RuO₂) film formed in accordance with the exemplary embodiments is formed in an upper portion of a ruthenium metal film. FIG. 7 is a diagram showing a case in which the ruthenium oxide (RuO₂) film formed in accordance with the exemplary embodiments is formed between a substrate and a ruthenium metal film, and in an upper portion of the ruthenium metal film.

In FIG. 1 described above, it is described that the ruthenium oxide film 100 is formed between the substrate S and the ruthenium metal film 10. However, the embodiment is not limited thereto, and the ruthenium oxide (RuO₂) film formed by the method in accordance with the embodiment may be formed at various locations.

For example, as illustrated in FIG. 6, the ruthenium oxide film 100 may be formed on the ruthenium metal film 10. Here, the ruthenium metal film 10 and the ruthenium oxide film 100 formed on the ruthenium metal film 10 may be components of an electrode. That is, the electrode may include the ruthenium metal film 10 and the ruthenium oxide film 100 formed on the ruthenium metal film 10.

The ruthenium oxide film 100 formed on the ruthenium metal film 10 increases the work function of the electrode. That is, the ruthenium metal film 10 has a low work function, and the ruthenium oxide film 100 has a high work function compared to the ruthenium metal film 10. Accordingly, the work function of the electrode may be improved by forming the ruthenium oxide film 100 on the ruthenium metal film 10. In addition, as the work function of the electrode is improved, a leakage current may be reduced.

As another example, as illustrated in FIG. 7, the ruthenium oxide film 100 may be formed in each of a lower portion and an upper portion of the ruthenium metal film 10. Here, the ruthenium metal film 10, and the ruthenium oxide film 100 formed in the upper portion and the lower portion of the ruthenium metal film 10 may be components of an electrode. That is, the electrode may include the ruthenium metal film 10, the ruthenium oxide film 100 formed in the lower portion of the ruthenium metal film 10, and the ruthenium oxide film 100 formed in the upper portion of the ruthenium metal film 10.

Here, the ruthenium oxide film 100 formed in the lower portion of the ruthenium metal film 10 serves as a diffusion barrier film which suppresses or prevents ruthenium (Ru) of the ruthenium metal film 10 from moving to the substrate S. In addition, the ruthenium oxide film 100 formed in the upper portion of the ruthenium metal film 10 may improve the work function of the electrode.

According to the method for forming a ruthenium oxide film in accordance with exemplary embodiments, it is possible to form the ruthenium oxide film 100 having a high oxygen content. That is, an oxygen-containing gas is sprayed to the ruthenium film 111, which is a precious metal, to form the primary ruthenium oxide film 110, and then the primary ruthenium oxide film 110 is exposed to plasma, so that oxygen may be easily penetrated into the primary ruthenium oxide film 110. That is, the amount of oxygen penetrating into the primary ruthenium oxide film 110 may be increased. Accordingly, the secondary ruthenium oxide film 100 having an increased oxygen content compared to the primary ruthenium oxide film 110 may be formed. Therefore, it is possible to form a ruthenium oxide (RuO₂) film having a higher oxygen content than a conventional ruthenium oxide film, and thus, it is possible to improve the quality of the ruthenium oxide film 100. That is, it is possible to improve the performance of the ruthenium oxide film 100 included in a semiconductor device.

### INDUSTRIAL APPLICABILITY

According to exemplary embodiments, it is possible to form a ruthenium oxide film having a high oxygen content. Therefore, it is possible to improve the quality of the ruthenium oxide film, and accordingly, it is possible to improve the performance of the ruthenium oxide film included in a semiconductor device.

1. A method for forming a ruthenium oxide film, the method comprising:
spraying a precursor containing ruthenium (Ru) toward a substrate to form a ruthenium film;
spraying an oxygen-containing gas onto the ruthenium film to form the ruthenium oxide film; and
forming a plasma to expose the ruthenium oxide film to the plasma.

2. The method of claim 1, wherein in the forming of the plasma, the oxygen-containing gas is used to form the plasma.

3. The method of claim 2, wherein the oxygen-containing gas comprises one or a combination of two or more of oxygen (O₂), ozone (O₃), and nitrous oxide (N₂O).

4. The method of claim 2, wherein the forming of the plasma comprises additionally using an inert gas in addition to the oxygen-containing gas to form the plasma, wherein the inert gas includes one or a combination of two or more of argon (Ar) and helium (He).

5. The method of claim 1, wherein the oxygen content of the ruthenium oxide film exposed to the plasma is higher than the oxygen content of the ruthenium oxide film before the exposure to the plasma.

6. The method of claim 1, wherein a film forming cycle (CY_{f}) including the forming of the ruthenium film and the forming of the ruthenium oxide film is performed a plurality of times, and the plurality of times of the film forming cycle (CY_{f}) is continuously performed.

7. The method of claim 6, wherein the exposing of the ruthenium oxide film to the plasma is performed after continuously performing the film forming cycle (CY_{f}) a plurality of times.

8. The method of claim 4, wherein in the forming of the plasma, the forming of the plasma by additionally using the inert gas in addition to the oxygen-containing gas comprises:
spraying the oxygen-containing gas and the inert gas toward the ruthenium oxide film; and
generating the plasma using the sprayed oxygen-containing gas and the inert gas,
wherein in the spraying of the oxygen-containing gas and the inert gas, the spraying is performed such that the flow rate of the oxygen-containing gas is greater than that of the inert gas.

9. The method of claim 6, wherein in the spraying of the oxygen-containing gas in the film forming cycle (CY_{f}), the inert gas is sprayed there together, wherein the inert gas includes one or a combination of two or more of argon (Ar) and helium (He).

10. The method of claim 9, wherein in the spraying of the oxygen-containing gas and the inert gas in the film forming cycle (CY_{f}), the spraying is performed such that the flow rate of the oxygen-containing gas is greater than that of the inert gas.

11. The method of claim 1, wherein in the forming of the ruthenium film, the forming of the ruthenium oxide film, and the exposing to the plasma, the temperature of the substrate is controlled to approximately 250 °C to approximately 450 °C.

12. A method for manufacturing a semiconductor device, the method comprising:
forming a ruthenium metal film on a substrate inside a chamber; and
before or after the forming of the ruthenium metal film, forming a ruthenium oxide film in situ inside the chamber in which the ruthenium metal film is formed,
wherein the forming of the ruthenium oxide film is performed by the method for forming a ruthenium oxide film described in claim 1.

13. The method of claim 12, wherein in the forming of the ruthenium metal film and the forming of the ruthenium oxide film, the temperature of the substrate is controlled to approximately 250 °C to approximately 450 °C.
